(19) United States
(12) Patent Application Publication
(10) Pub. No.: US 2023/0034531 A1
(43) Pub. Date: Feb. 2, 2023

(54) POWER AMPLIFIER WITH OVERVOLTAGE PROTECTION IN INPUT MATCHING STAGE

(71) Applicant: QUALCOMM Incorporated, San Diego, CA (US)

(72) Inventors: Zhenying LUO, Wayland, MA (US); Yazhou WANG, Westford, MA (US); Xinwei WANG, Dunstable, MA (US); Jing-Hwa CHEN, Acton, MA (US); Xiangdong ZHANG, Westford, MA (US)

(21) Appl. No.: 17/390,166

(22) Filed: Jul. 30, 2021

(51) Int. Cl. H03F 3/24; H03F 1/52; H03F 1/56; H03F 3/195

(52) U.S. Cl. CPC H03F 3/245; H03F 1/52; H03F 1/565; H03F 3/195; H03F 2200/451; H03F 2200/318; H03F 2200/441

(57) ABSTRACT

Methods and apparatus for limiting the input voltage (swing) of a power amplifier, such as a power amplifier in a radio frequency (RF) front-end of a wireless device. One example radio frequency front-end circuit generally includes a power amplifier, a matching circuit having an output coupled to an input of the power amplifier, and an overvoltage protection circuit coupled to the matching circuit. With an overvoltage protection circuit coupled to the matching circuit in this manner, the power amplifier may have enhanced ruggedness performance.

### TECHNICAL FIELD

Certain aspects of the present disclosure generally relate to electronic circuits and, more particularly, to overvoltage protection for a power amplifier.

### BACKGROUND

Electronic devices include computing devices such as desktop computers, notebook computers, tablet computers, smartphones, wearable devices like a smartwatch, internet servers, and so forth. These various electronic devices provide information, entertainment, social interaction, security, safety, productivity, transportation, manufacturing, and other services to human users. These various electronic devices depend on wireless communications for many of their functions. Wireless communication systems and devices are widely deployed to provide various types of communication content such as voice, video, packet data, messaging, broadcast, and so on. These systems may be capable of supporting communication with multiple users by sharing available system resources (e.g., time, frequency, and/or power). Examples of such systems include code division multiple access (CDMA) systems, time division multiple access (TDMA) systems, frequency division multiple access (FDMA) systems, and orthogonal frequency division multiple access (OFDMA) systems (e.g., a Long Term Evolution (LTE) system or a New Radio (NR) system).

A wireless communication network may include a number of base stations that can support communication for a number of mobile stations. A mobile station (MS) may communicate with a base station (BS) via a downlink and an uplink. The downlink (or forward link) refers to the communication link from the base station to the mobile station, and the uplink (or reverse link) refers to the communication link from the mobile station to the base station. A base station may transmit data and control information on the downlink to a mobile station and/or may receive data and control information on the uplink from the mobile station. The base station and/or the mobile station may include a radio frequency front-end with a power amplifier coupled to one or more antennas for transmission.

### SUMMARY

The systems, methods, and devices of the disclosure each have several aspects, no single one of which is solely responsible for its desirable attributes. Without limiting the scope of this disclosure as expressed by the claims that follow, some features are discussed briefly below. After considering this discussion, and particularly after reading the section entitled “Detailed Description,” one will understand how the features of this disclosure provide the advantages described herein.

Certain aspects of the present disclosure generally relate to overvoltage protection for a power amplifier (e.g., a power amplifier in a radio frequency front-end of a wireless device).

Certain aspects of the present disclosure provide a radio frequency front-end circuit. The circuit generally includes a power amplifier, a matching circuit having an output coupled to an input of the power amplifier, and an overvoltage protection circuit coupled to the matching circuit.

Certain aspects of the present disclosure provide a wireless device comprising the radio frequency front-end circuit described herein. The wireless device generally further includes at least one antenna coupled an output of the power amplifier and a transmit chain coupled to an input of the matching circuit.

Certain aspects of the present disclosure provide a method of signal processing. The method generally includes receiving a signal at a matching circuit; limiting a voltage of the signal with an overvoltage protection circuit coupled to the matching circuit; and amplifying the signal with a power amplifier.

Certain aspects of the present disclosure provide an apparatus. The apparatus generally includes means for impedance matching; means for limiting a voltage of a signal, the means for limiting being coupled to the means for impedance matching; and means for amplifying the signal, the means for amplifying having an input coupled to an output of the means for impedance matching.

To the accomplishment of the foregoing and related ends, the one or more aspects comprise the features hereinafter fully described and particularly pointed out in the claims. The following description and the appended drawings set forth in detail certain illustrative features of the one or more aspects. These features are indicative, however, of but a few of the various ways in which the principles of various aspects may be employed.

### BRIEF DESCRIPTION OF THE DRAWINGS

So that the manner in which the above-recited features of the present disclosure can be understood in detail, a more particular description, briefly summarized above, may be had by reference to aspects, some of which are illustrated in the appended drawings. It is to be noted, however, that the appended drawings illustrate only certain typical aspects of this disclosure and are therefore not to be considered limiting of its scope, for the description may admit to other equally effective aspects.

FIG. 1 is a diagram of an example wireless communications network, in which aspects of the present disclosure may be practiced.

FIG. 2 is a block diagram of an example access point (AP) and example user terminals, in which aspects of the present disclosure may be practiced.

FIG. 3 is a block diagram of an example transceiver front-end, in which aspects of the present disclosure may be practiced.

FIG. 4A is a block diagram of a portion of an example transmitter front-end, illustrating an overvoltage protection circuit coupled to a matching circuit at an input of a power amplifier, in accordance with certain aspects of the present disclosure.

FIG. 4B is a circuit diagram illustrating example components for the matching circuit and for the overvoltage protection circuit of FIG. 4A, in accordance with certain aspects of the present disclosure.

FIG. 5 is a flow diagram of example operations for signal processing, in accordance with certain aspects of the present disclosure.

To facilitate understanding, identical reference numerals have been used, where possible, to designate identical elements that are common to the figures. It is contemplated that elements disclosed in one aspect may be beneficially utilized on other aspects without specific recitation.

### DETAILED DESCRIPTION

Certain aspects of the present disclosure provide techniques and apparatus for limiting the input voltage (swing) of a power amplifier, such as a power amplifier in a radio frequency front-end of a wireless device. One example radio frequency front-end circuit generally includes a power amplifier, a matching circuit having an output coupled to an input of the power amplifier, and an overvoltage protection circuit coupled to the matching circuit. With an overvoltage protection circuit coupled to the matching circuit in this manner, the power amplifier may be less susceptible to failures due to breakdown voltage of the power amplifier transistor and may thus have an increased ruggedness rating.

Various aspects of the disclosure are described more fully hereinafter with reference to the accompanying drawings. This disclosure may, however, be embodied in many different forms and should not be construed as limited to any specific structure or function presented throughout this disclosure. Rather, these aspects are provided so that this disclosure will be thorough and complete, and will fully convey the scope of the disclosure to those skilled in the art. Based on the teachings herein one skilled in the art should appreciate that the scope of the disclosure is intended to cover any aspect of the disclosure disclosed herein, whether implemented independently of or combined with any other aspect of the disclosure. For example, an apparatus may be implemented or a method may be practiced using any number of the aspects set forth herein. In addition, the scope of the disclosure is intended to cover such an apparatus or method which is practiced using other structure, functionality, or structure and functionality in addition to or other than the various aspects of the disclosure set forth herein. It should be understood that any aspect of the disclosure disclosed herein may be embodied by one or more elements of a claim.

The word “exemplary” is used herein to mean “serving as an example, instance, or illustration.” Any aspect described herein as “exemplary” is not necessarily to be construed as preferred or advantageous over other aspects.

As used herein, the term “connected with” in the various tenses of the verb “connect” may mean that element A is directly connected to element B or that other elements may be connected between elements A and B (i.e., that element A is indirectly connected with element B). In the case of electrical components, the term “connected with” may also be used herein to mean that a wire, trace, or other electrically conductive material is used to electrically connect elements A and B (and any components electrically connected therebetween).

The techniques described herein may be used in combination with various wireless technologies such as Code Division Multiple Access (CDMA), Orthogonal Frequency Division Multiplexing (OFDM), Time Division Multiple Access (TDMA), Spatial Division Multiple Access (SDMA), Single Carrier Frequency Division Multiple Access (SC-FDMA), Time Division Synchronous Code Division Multiple Access (TD-SCDMA), and so on. Multiple user terminals can concurrently transmit/receive data via different (1) orthogonal code channels for CDMA, (2) time slots for TDMA, or (3) sub-bands for OFDM. A CDMA system may implement IS-2000, IS-95, IS-856, Wideband-CDMA (W-CDMA), or some other standards. An OFDM system may implement Institute of Electrical and Electronics Engineers (IEEE) 802.11, IEEE 802.16, Long Term Evolution (LTE) (e.g., in TDD and/or FDD modes), or some other standards (e.g., 5G). A TDMA system may implement Global System for Mobile Communications (GSM) or some other standards. In some implementations, the techniques described herein may be used in combination with a wireless local area network (WLAN), for example utilizing a WiFi standard, such as one of the IEEE 802.11 standards. These various standards are known in the art.

### An Example Wireless System

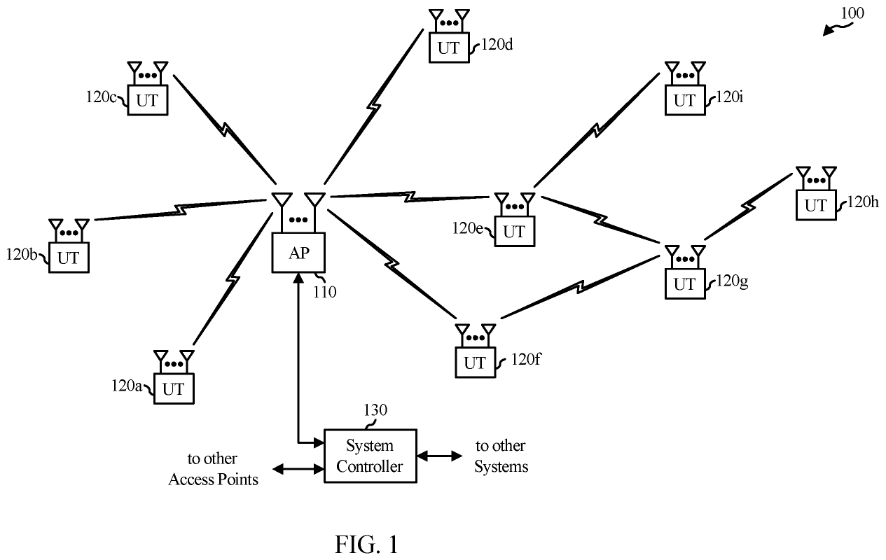

FIG. 1 illustrates a wireless communications system 100 with access points 110 and user terminals 120, in which aspects of the present disclosure may be practiced. For simplicity, only one access point 110 is shown in FIG. 1. An access point (AP) is generally a fixed station that communicates with the user terminals and may also be referred to as a base station (BS), an evolved Node B (eNB), or some other terminology. A user terminal (UT) may be fixed or mobile and may also be referred to as a mobile station (MS), an access terminal, user equipment (UE), a station (STA), a client, a wireless device, or some other terminology. A user terminal may be a wireless device, such as a cellular phone, a personal digital assistant (PDA), a handheld device, a wireless modem, a laptop computer, a tablet, a personal computer, etc.

Access point 110 may communicate with one or more user terminals 120 at any given moment on the downlink and uplink. The downlink (i.e., forward link) is the communication link from the access point to the user terminals, and the uplink (i.e., reverse link) is the communication link from the user terminals to the access point. A user terminal may also communicate peer-to-peer with another user terminal. A system controller 130 couples to and provides coordination and control for the access points.

Wireless communications system 100 may employ multiple transmit and multiple receive antennas for data transmission on the downlink and uplink. For example, access point 110 may be equipped with a number Nₐₚ of antennas to achieve transmit diversity for downlink transmissions and/or receive diversity for uplink transmissions. A set Nu of selected user terminals 120 may receive downlink transmissions and transmit uplink transmissions. Each selected user terminal transmits user-specific data to and/or receives user-specific data from the access point. In general, each selected user terminal may be equipped with one or multiple antennas (i.e., Nᵤₜ≤1). The Nu selected user terminals can have the same or different number of antennas.

Wireless communications system 100 may be a time division duplex (TDD) system or a frequency division duplex (FDD) system. For a TDD system, the downlink and uplink share the same frequency band. For an FDD system, the downlink and uplink use different frequency bands. Wireless communications system 100 may also utilize a single carrier or multiple carriers for transmission. Each user terminal 120 may be equipped with a single antenna (e.g., in order to keep costs down) or multiple antennas (e.g., where the additional cost can be supported).

The access point 110 and/or user terminal 120 may include an overvoltage protection circuit for an input of a power amplifier, in accordance with certain aspects of the present disclosure.

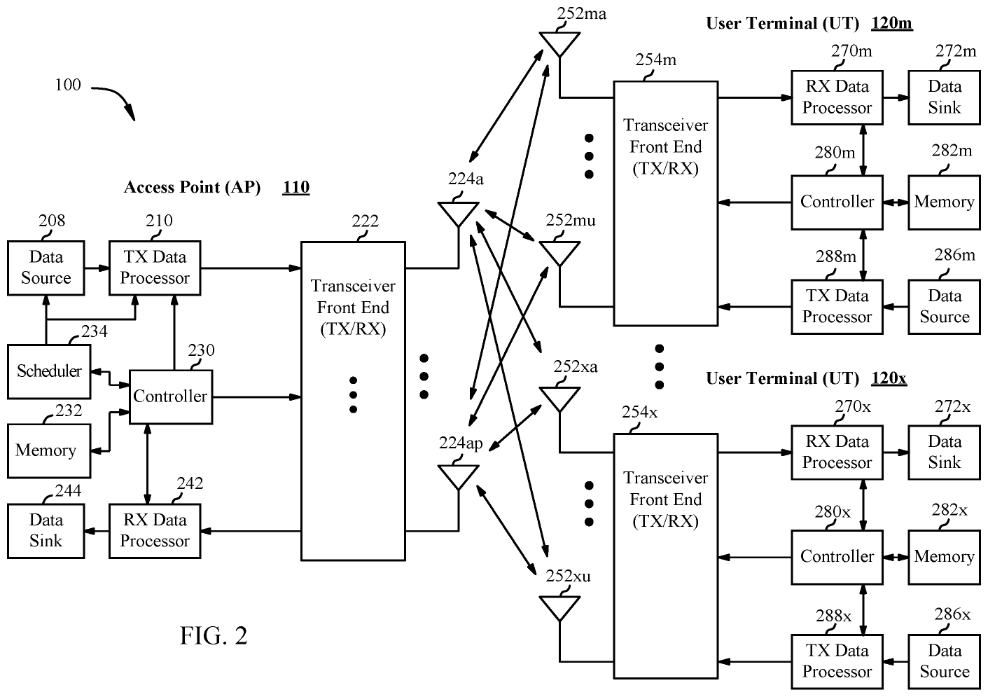

FIG. 2 shows a block diagram of access point 110 and two user terminals 120m and 120x in wireless communications system 100. Access point 110 is equipped with Nₐₚ antennas 224a through 224ap. User terminal 120m is equipped with N_{ut,m} antennas 252ma through 252mu, and user terminal 120x is equipped with N_{ut,x} antennas 252xa through 252xu. Access point 110 is a transmitting entity for the downlink and a receiving entity for the uplink. Each user terminal 120 is a transmitting entity for the uplink and a receiving entity for the downlink. As used herein, a “transmitting entity” is an independently operated apparatus or device capable of transmitting data via a frequency channel, and a “receiving entity” is an independently operated apparatus or device capable of receiving data via a frequency channel. In the following description, the subscript “dn” denotes the downlink, the subscript “up” denotes the uplink, Nᵤₚ user terminals are selected for simultaneous transmission on the uplink, N_{dn} user terminals are selected for simultaneous transmission on the downlink, Nᵤₚ may or may not be equal to N_{dn}, and Nᵤₚ and N_{dn} may be static values or can change for each scheduling interval. Beam-steering or some other spatial processing technique may be used at the access point and user terminal.

On the uplink, at each user terminal 120 selected for uplink transmission, a TX data processor 288 receives traffic data from a data source 286 and control data from a controller 280. TX data processor 288 processes (e.g., encodes, interleaves, and modulates) the traffic data {dᵤₚ} for the user terminal based on the coding and modulation schemes associated with the rate selected for the user terminal and provides a data symbol stream {sᵤₚ} for one of the N_{ut,m} antennas. A transceiver front-end (TX/RX) 254 (also known as a radio frequency front-end (RFFE)) receives and processes (e.g., converts to analog, amplifies, filters, and frequency upconverts) a respective symbol stream to generate an uplink signal. The transceiver front-end 254 may also route the uplink signal to one of the N_{ut,m} antennas for transmit diversity via an RF switch, for example. The controller 280 may control the routing within the transceiver front-end 254. Memory 282 may store data and program codes for the user terminal 120 and may interface with the controller 280.

A number Nᵤₚ of user terminals 120 may be scheduled for simultaneous transmission on the uplink. Each of these user terminals transmits its set of processed symbol streams on the uplink to the access point.

At access point 110, Nₐₚ antennas 224a through 224ap receive the uplink signals from all Nᵤₚ user terminals transmitting on the uplink. For receive diversity, a transceiver front-end 222 may select signals received from one of the antennas 224 for processing. The signals received from multiple antennas 224 may be combined for enhanced receive diversity. The access point's transceiver front-end 222 also performs processing complementary to that performed by the user terminal's transceiver front-end 254 and provides a recovered uplink data symbol stream. The recovered uplink data symbol stream is an estimate of a data symbol stream {sᵤₚ} transmitted by a user terminal. An RX data processor 242 processes (e.g., demodulates, deinterleaves, and decodes) the recovered uplink data symbol stream in accordance with the rate used for that stream to obtain decoded data. The decoded data for each user terminal may be provided to a data sink 244 for storage and/or a controller 230 for further processing.

The transceiver front-end (TX/RX) 222 of access point 110 and/or transceiver front-end 254 of user terminal 120 may include an overvoltage protection circuit for an input of a power amplifier, in accordance with certain aspects of the present disclosure.

On the downlink, at access point 110, a TX data processor 210 receives traffic data from a data source 208 for N_{dn} user terminals scheduled for downlink transmission, control data from a controller 230 and possibly other data from a scheduler 234. The various types of data may be sent on different transport channels. TX data processor 210 processes (e.g., encodes, interleaves, and modulates) the traffic data for each user terminal based on the rate selected for that user terminal. TX data processor 210 may provide a downlink data symbol streams for one of more of the N_{dn} user terminals to be transmitted from one of the Nₐₚ antennas. The transceiver front-end 222 receives and processes (e.g., converts to analog, amplifies, filters, and frequency upconverts) the symbol stream to generate a downlink signal. The transceiver front-end 222 may also route the downlink signal to one or more of the Nₐₚ antennas 224 for transmit diversity via an RF switch, for example. The controller 230 may control the routing within the transceiver front-end 222. Memory 232 may store data and program codes for the access point 110 and may interface with the controller 230.

At each user terminal 120, N_{ut,m} antennas 252 receive the downlink signals from access point 110. For receive diversity at the user terminal 120, the transceiver front-end 254 may select signals received from one of the antennas 252 for processing. The signals received from multiple antennas 252 may be combined for enhanced receive diversity. The user terminal's transceiver front-end 254 also performs processing complementary to that performed by the access point's transceiver front-end 222 and provides a recovered downlink data symbol stream. An RX data processor 270 processes (e.g., demodulates, deinterleaves, and decodes) the recovered downlink data symbol stream to obtain decoded data for the user terminal. The decoded data for the user terminal may be provided to a data sink 272 for storage and/or a controller 280 for further processing.

Those skilled in the art will recognize the techniques described herein may be generally applied in systems utilizing any type of multiple access schemes, such as TDMA, SDMA, Orthogonal Frequency Division Multiple Access (OFDMA), CDMA, SC-FDMA, TD-SCDMA, and combinations thereof.

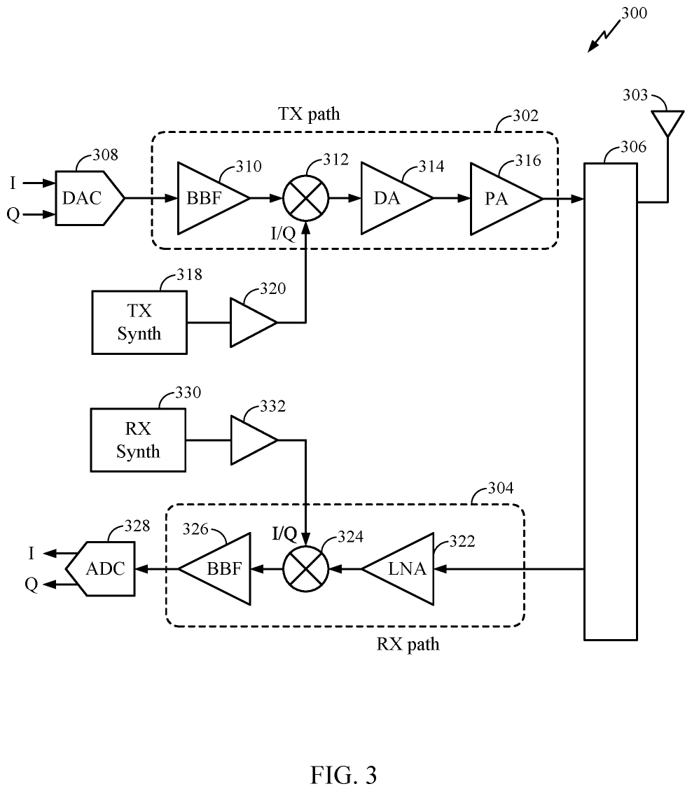

FIG. 3 is a block diagram of an example transceiver front-end 300, such as transceiver front-ends 222, 254 in FIG. 2, in which aspects of the present disclosure may be practiced. The transceiver front-end 300 includes a transmit (TX) path 302 (also known as a “transmit chain”) for transmitting signals via one or more antennas and a receive (RX) path 304 (also known as a “receive chain”) for receiving signals via the antennas. When the TX path 302 and the RX path 304 share an antenna 303, the paths may be connected with the antenna via an interface 306, which may include any of various suitable RF devices, such as a duplexer, a switch, a diplexer, and the like.

Receiving in-phase (I) or quadrature (Q) baseband analog signals from a digital-to-analog converter (DAC) 308, the TX path 302 may include a baseband filter (BBF) 310, a mixer 312, a driver amplifier (DA) 314, and a power amplifier (PA) 316. The BBF 310, the mixer 312, and the DA 314 may be included in a radio frequency integrated circuit (RFIC), while the PA 316 may be external to the RFIC. The BBF 310 filters the baseband signals received from the DAC 308, and the mixer 312 mixes the filtered baseband signals with a transmit local oscillator (LO) signal to convert the baseband signal of interest to a different frequency (e.g., upconvert from baseband to RF). This frequency-conversion process produces the sum and difference frequencies of the LO frequency and the frequency of the signal of interest. The sum and difference frequencies are referred to as the beat frequencies. The beat frequencies are typically in the RF range, such that the signals output by the mixer 312 are typically RF signals, which may be amplified by the DA 314 and/or by the PA 316 before transmission by the antenna 303.

The RX path 304 includes a low noise amplifier (LNA) 322, a mixer 324, and a baseband filter (BBF) 326. The LNA 322, the mixer 324, and the BBF 326 may be included in a radio frequency integrated circuit (RFIC), which may or may not be the same RFIC that includes the TX path components. RF signals received via the antenna 303 may be amplified by the LNA 322, and the mixer 324 mixes the amplified RF signals with a receive local oscillator (LO) signal to convert the RF signal of interest to a different baseband frequency (i.e., downconvert). The baseband signals output by the mixer 324 may be filtered by the BBF 326 before being converted by an analog-to-digital converter (ADC) 328 to digital I or Q signals for digital signal processing.

In some aspects, there may be various impedance matching networks (also known as power matching networks) between certain stages of the TX path 302 and the RX path 304. For example, in the TX path 302, there may be impedance matching networks at the input of the DA 314, at the output of the PA 316, and/or between the output of the DA 314 and the input of the PA 316. According to aspects of the present disclosure, an overvoltage protection circuit may be coupled to at least one of these matching circuits, such as to a matching circuit coupled to the input of the PA 316. Examples of such an overvoltage protection circuit are described below.

Contemporary systems may employ frequency synthesizers with a voltage-controlled oscillator (VCO) to generate a stable, tunable LO with a particular tuning range. Thus, the transmit LO frequency may be produced by a TX frequency synthesizer 318, which may be buffered or amplified by amplifier 320 before being mixed with the baseband signals in the mixer 312. Similarly, the receive LO frequency may be produced by an RX frequency synthesizer 330, which may be buffered or amplified by amplifier 332 before being mixed with the RF signals in the mixer 324. For some aspects, a frequency synthesizer may be shared by the TX and the RX and/or by multiple TX and/or RX chains.

### Example Overvoltage Protection for a Power Amplifier

Design specifications such as ruggedness for a power amplifier (e.g., power amplifier (PA) 316) are becoming more challenging due to higher output power ratings. The ruggedness specification may also become more difficult to meet with higher power supply voltages (e.g., increasing from 3.4 to 5 V) for the power amplifier and/or at higher temperatures. Such conditions may lead to high voltage across the power transistor (also referred to as the “power cell transistor”) in the final stage of the power amplifier that may exceed this transistor's breakdown voltage, which may likely damage the power amplifier.

To improve the ruggedness of the power amplifier, certain aspects of the present disclosure provide techniques and apparatus for protecting the input of the power amplifier. Such protection includes an overvoltage protection circuit that limits the voltage (swing), and hence the maximum power, entering the power transistor in the final stage of the power amplifier. By preventing the power transistor from receiving an input voltage that meets or exceeds the transistor's breakdown voltage, the overvoltage protection circuit improves the ruggedness of the power amplifier.

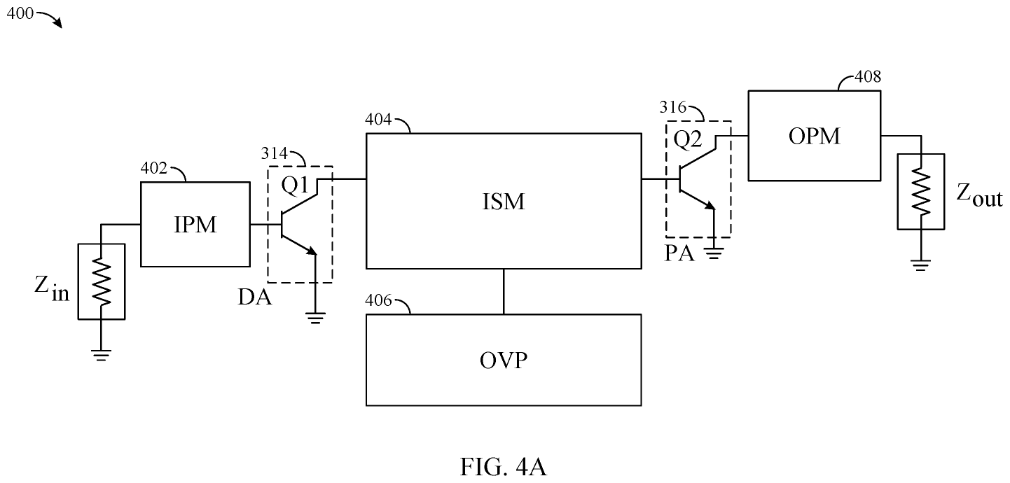

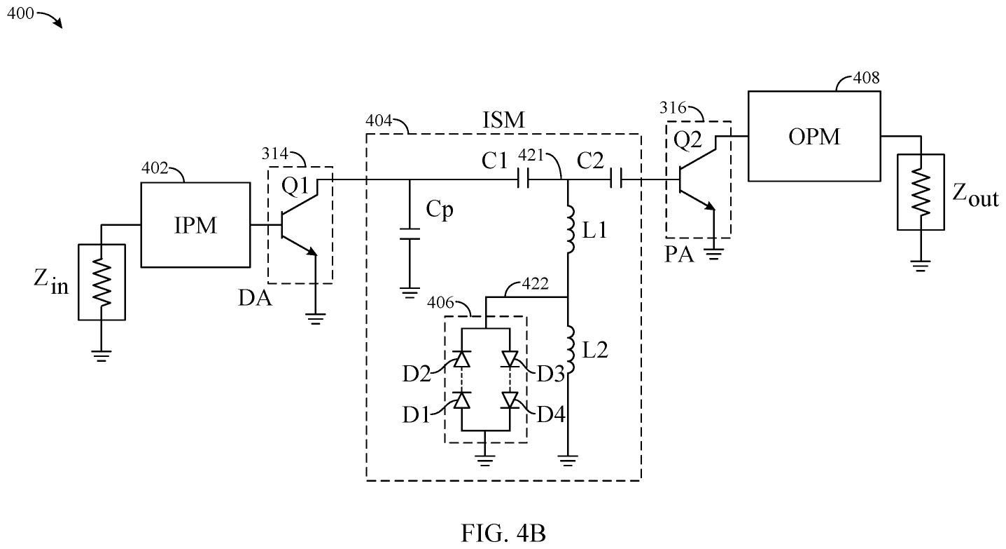

For example, FIG. 4A is a block diagram of an example transmitter front-end circuit 400 (also referred to as, or as part of, a radio frequency front-end circuit), in accordance with certain aspects of the present disclosure. As shown, the transmitter front-end circuit 400 includes an input impedance Zᵢₙ, an input power matching (IPM) circuit 402, a driver amplifier (DA) 314, an inter-stage matching (ISM) circuit 404, a power amplifier (PA) 316, an output power matching (OPM) circuit 408, and an output impedance Zₒᵤₜ. To limit the input voltage (swing) of the PA 316, thereby increasing the ruggedness performance, the transmitter front-end circuit 400 also includes an overvoltage protection circuit 406 coupled to (or included in) the ISM circuit 404.

The power amplifier 316 may include a transistor Q2 (the power cell transistor). For certain aspects, transistor Q2 may be implemented by a heterojunction bipolar transistor (HBT) and/or be composed of gallium arsenide (GaAs). The collector of transistor Q2 may be coupled to the OPM circuit 408, as illustrated in FIG. 4A. The collector of transistor Q2 may also be coupled to a power supply rail for the power amplifier via a series inductor, for example, which may have a shunt decoupling capacitor coupled to a terminal of the inductor, between the power supply rail and a reference potential node (e.g., electrical ground) for the circuit 400. The base of transistor Q2 may be coupled to an output of the ISM circuit 404, and the emitter of transistor Q2 may be coupled to the reference potential node for the circuit 400. The output of the power amplifier 316 (e.g., the collector of transistor Q2) may be coupled to an input of the OPM circuit 408. The output impedance Zₒᵤₜ may represent the load impedance for the circuit 400, which may include one or more antennas and an interface (e.g., interface 306) for connecting to the one or more antennas. An output of the OPM circuit 408 may be coupled to the output impedance Zₒᵤₜ, and the OPM circuit 408 may be used for matching the impedance looking into the collector of transistor Q2 to the output impedance Zₒᵤₜ, in an effort to minimize power loss and maximize power transmission in the circuit 400.

The DA 314 may include a transistor Q1. For certain aspects, transistor Q1 may be implemented by an HBT and/or be composed of GaAs. The input of the ISM circuit 404 may be coupled to the collector of transistor Q1. The collector of transistor Q1 may also be coupled to a power supply rail for the driver amplifier via another series inductor, for example, which may have another shunt decoupling capacitor coupled to a terminal of the other inductor, between the power supply rail and the reference potential node for the circuit 400. The power supply rail for the driver amplifier may have a different voltage than the power supply rail for the power amplifier. The base of transistor Q1 may be coupled to the input impedance Zᵢₙ via the IPM circuit 402. The input impedance Zᵢₙ may represent the source impedance for the circuit 400, which may include an output impedance of a portion of the transmit chain (e.g., the mixer 312) coupled to an input of the IPM circuit 402 and to the DA 314. An output of the IPM circuit 402 may be coupled to the base of transistor Q1, and the IPM circuit 402 may be used for matching the impedance looking into the base of transistor Q1 to the input impedance Zᵢₙ, in an effort to minimize power loss and maximize power transmission in the circuit 400. The emitter of transistor Q1 may also be coupled to the reference potential node.

FIG. 4B is a circuit diagram illustrating example components for the ISM circuit 404 and for the overvoltage protection circuit 406 in the transmitter front-end circuit 400 of FIG. 4A, in accordance with certain aspects of the present disclosure. The ISM circuit 404 may include a H-network (also referred to as a pi-network) having two shunt branches with a series branch therebetween or a T-network (also referred to as a Y-network) having two series branches with a shunt branch therebetween. Each series or shunt branch of the ISM circuit 404 may include one or more passive components (e.g., one or more inductors and/or capacitors)—which may be coupled in series or in parallel with other components in that branch—to get the desired impedance value in each branch at the frequency (or frequency range) of interest. As illustrated in FIG. 4B, the ISM circuit 404 is a T-network with a first series impedance (represented by capacitor C1), a second series impedance (represented by capacitor C2) coupled in series with the first series impedance at a node 421, and a shunt impedance (represented by two series-connected inductors L1 and L2) coupled between the node 421 and the reference potential node. The two inductors L1 and L2 may be coupled in series at a node 422. For certain aspects, the two inductors L1 and L2 may be considered as two portions of a single inductor having a tap therebetween at node 422. The ISM circuit 404 may also include parasitic shunt capacitance, modeled by parasitic capacitor Cp, in some cases.

For certain aspects, the overvoltage protection circuit 406 may be coupled to a tap of a shunt passive component (or between two series-connected shunt passive components) in the ISM circuit 404. For example, the overvoltage protection circuit 406 may be coupled to the node 422 between the two inductors L1 and L2, effectively coupled in parallel with the inductor L2.

The overvoltage protection circuit 406 may include one or more diode devices arranged in any of various suitable configurations to limit the voltage (e.g., clamp the voltage) seen at the output of the ISM circuit 404 and by the input to the PA 316. For example, the overvoltage protection circuit 406 may have a single branch, two branches as illustrated in FIG. 4B, or more than two branches. The diode devices may be implemented by any of various suitable elements having a p-n junction, such as diodes or diode-connected transistors. The diode devices may be implemented with the same or different semiconductor technology (e.g., GaAs HBT) as the power cell transistor Q2 of the power amplifier 316. For certain aspects, one, two, or more diode devices may be connected serially in each branch of the overvoltage protection circuit 406. The number of diode devices in each branch may be the same or different. Furthermore, a branch of the overvoltage protection circuit 406 may include more than one type of diode device, or different branches may include more than one type of diode device (e.g., normal diode with a forward voltage drop of 0.6 V versus a Schottky diode having a forward voltage drop of 0.2 V). The voltage limit of a branch of the overvoltage protection circuit 406 may be designed to be less than the breakdown voltage of transistor Q2 in the PA 316.

As illustrated in FIG. 4B, diodes D1 and D2 are connected in series in a first direction in a first branch of the overvoltage protection circuit 406. Diodes D3 and D4 are connected in series in a second direction in a second branch of the overvoltage protection circuit 406. The second direction is opposite to the first direction, such that the series-connected diodes D3 and D4 are anti-parallel to the series-connected diodes D1 and D2.

In the overvoltage protection circuit 406, the forward voltage of the diode devices (due to the diode device type), the number of diode devices, and/or the arrangement of the diode devices may be manipulated in order to set the level at which the clamping will occur (e.g., the clamping voltage). By coupling the overvoltage protection circuit 406 to a tap of an inductive element (e.g., to the node 422 between inductors L1 and L2), the inductive element will act as a voltage divider, which may allow for finer tuning of the clamping voltage of the overvoltage protection circuit 406. In this manner, the overvoltage protection circuit 406 may be used to limit the amount of power seen by the power amplifier 316, thus increasing the ruggedness of the amplifier.

### Example Operations

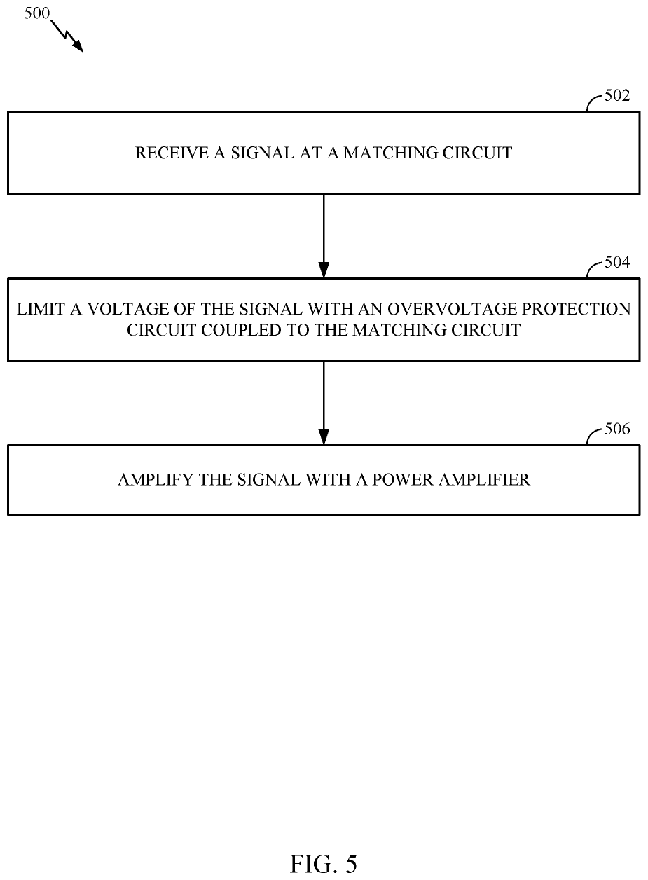

FIG. 5 is a flow diagram of example operations 500 for signal processing, in accordance with certain aspects of the present disclosure. The operations 500 may be performed by a radio frequency front-end circuit, such as the transmitter front-end circuit 400 of FIG. 4A or 4B.

The operations 500 may begin at block 502 by receiving a signal at a matching circuit (e.g., the ISM circuit 404). At block 504, an overvoltage protection (OVP) circuit (e.g., the overvoltage protection circuit 406) coupled to the matching circuit may limit a voltage of the received signal. At block 506, the signal may be amplified with a power amplifier (e.g., the PA 316). The input of the power amplifier may be coupled to an output of the matching circuit.

According to certain aspects, the limiting at block 504 may involve clamping the voltage of the signal with a single branch of one or more diodes (e.g., diodes D1, D2, D3, and/or D4) in the overvoltage protection circuit. For certain aspects, the limiting at block 504 may include clamping the voltage of the signal with a plurality of series-connected diodes (e.g., diodes D1 and D2 or diodes D3 and D4) in the overvoltage protection circuit. For certain aspects, the limiting at block 504 may involve clamping a voltage swing of the signal with: (1) a first branch of the overvoltage protection circuit, the first branch having one or more first diodes (e.g., diode D1 and D2) arranged in a first direction, and (2) a second branch of the overvoltage protection circuit, the second branch having one or more second diodes (e.g., diodes D3 and D4) arranged in a second direction. The second direction may be opposite to the first direction, such that the one or more first diodes in the first branch are anti-parallel with the one or more second diodes in the second branch. A first number of the one or more first diodes in the first branch may be the same as or different from a second number of the one or more second diodes in the second branch. The first branch may comprise a first diode (e.g., diode D1) coupled in series with a second diode (e.g., diode D2). In this case, the first diode may be the same diode type or a different diode type than that of the second diode. In some cases, a first diode type (e.g., normal or Schottky) of at least one of the first diodes in the first branch may be different from a second diode type (e.g., Schottky or normal) of at least one of the second diodes in the second branch.

According to certain aspects, the operations 500 may further involve amplifying another signal with a driver amplifier (e.g., DA 314) to generate the signal for the receiving at the matching circuit.

According to certain aspects, the matching circuit may comprise a shunt passive component (e.g., a shunt inductor). In this case, the overvoltage protection circuit may be coupled to a tap of the shunt passive component. For other aspects, the matching circuit may include a shunt branch having a first passive component connected in series to a second passive component. In this case, the overvoltage protection circuit may be coupled to a node (e.g., node 422) between the first passive component and the second passive component. The first passive component may be an inductor (e.g., inductor L1), and the second passive component may be an inductor (e.g., inductor L2), as illustrated in FIG. 4B.

For certain aspects, an input of the matching circuit may be coupled to an output of a driver amplifier (e.g., DA 314, and more particularly to a collector of an output-stage transistor in the DA 314).

### Example Clauses

In addition to the various aspects described above, specific combinations of aspects are within the scope of the disclosure, some of which are detailed in the clauses below:

Clause 1: A radio frequency front-end circuit comprising a power amplifier, a matching circuit having an output coupled to an input of the power amplifier, and an overvoltage protection circuit coupled to the matching circuit.

Clause 2: The radio frequency front-end circuit of Clause 1, wherein the overvoltage protection circuit comprises a single branch of one or more diodes.

Clause 3: The radio frequency front-end circuit of Clause 1, wherein the overvoltage protection circuit comprises a single branch with a plurality of series-connected diodes.

Clause 4: The radio frequency front-end circuit of Clause 1, wherein the overvoltage protection circuit comprises a first branch of one or more first diodes arranged in a first direction and a second branch of one or more second diodes arranged in a second direction.

Clause 5: The radio frequency front-end circuit of Clause 4, wherein the second direction is opposite to the first direction, such that the one or more first diodes in the first branch are anti-parallel with the one or more second diodes in the second branch.

Clause 6: The radio frequency front-end circuit of Clause 4 or 5, wherein a first number of the one or more first diodes in the first branch is different from a second number of the one or more second diodes in the second branch.

Clause 7: The radio frequency front-end circuit of any of Clauses 4-6, wherein the first branch comprises a first diode coupled in series with a second diode and wherein the first diode is a different diode type than the second diode.

Clause 8: The radio frequency front-end circuit of any of Clauses 4-7, wherein a first diode type of at least one of the first diodes in the first branch is different from a second diode type of at least one of the second diodes in the second branch.

Clause 9: The radio frequency front-end circuit of any of the preceding Clauses, wherein the matching circuit comprises a shunt passive component and wherein the overvoltage protection circuit is coupled to a tap of the shunt passive component.

Clause 10: The radio frequency front-end circuit of Clause 9, wherein the shunt passive component comprises an inductor.

Clause 11: The radio frequency front-end circuit of any of Clauses 1-8, wherein the matching circuit comprises a shunt branch having a first passive component connected in series to a second passive component and wherein the overvoltage protection circuit is coupled to a node between the first passive component and the second passive component.

Clause 12: The radio frequency front-end circuit of Clause 11, wherein at least one of the first passive component or the second passive component comprises an inductor.

Clause 13: The radio frequency front-end circuit of Clause 11 or 12, wherein the second passive component comprises a capacitor.

Clause 14: The radio frequency front-end circuit of any of the preceding Clauses, further comprising a driver amplifier, wherein an output of the driver amplifier is coupled to an input of the matching circuit.

Clause 15: A method of signal processing, comprising receiving a signal at a matching circuit, limiting a voltage of the signal with an overvoltage protection circuit coupled to the matching circuit, and amplifying the signal with a power amplifier.

Clause 16: The method of Clause 15, wherein the limiting comprises clamping the voltage of the signal with a single branch of one or more diodes in the overvoltage protection circuit.

Clause 17: The method of Clause 15 or 16, wherein the limiting comprises clamping the voltage of the signal with a plurality of series-connected diodes in the overvoltage protection circuit.

Clause 18: The method of Clause 15, wherein the limiting comprises clamping a voltage swing of the signal with: a first branch of the overvoltage protection circuit, the first branch having one or more first diodes arranged in a first direction; and a second branch of the overvoltage protection circuit, the second branch having one or more second diodes arranged in a second direction.

Clause 19: The method of Clause 18, wherein the second direction is opposite to the first direction, such that the one or more first diodes in the first branch are anti-parallel with the one or more second diodes in the second branch.

Clause 20: The method of Clause 18 or 19, wherein a first number of the one or more first diodes in the first branch is different from a second number of the one or more second diodes in the second branch.

Clause 21: The method of any of Clauses 18-20, wherein the first branch comprises a first diode coupled in series with a second diode and wherein the first diode is a different diode type than the second diode.

Clause 22: The method of any of Clauses 18-21, wherein a first diode type of at least one of the first diodes in the first branch is different from a second diode type of at least one of the second diodes in the second branch.

Clause 23: The method of any of Clauses 15-22, further comprising amplifying another signal with a driver amplifier to generate the signal for the receiving at the matching circuit.

Clause 24: The method of any of Clauses 15-23, wherein the matching circuit comprises a shunt passive component and wherein the overvoltage protection circuit is coupled to a tap of the shunt passive component.

Clause 25: The method of any of Clauses 15-23, wherein the matching circuit comprises a shunt branch having a first passive component connected in series to a second passive component and wherein the overvoltage protection circuit is coupled to a node between the first passive component and the second passive component.

Clause 26: An apparatus for signal processing, comprising: means for impedance matching; means for limiting a voltage of a signal, the means for limiting being coupled to the means for impedance matching; and means for amplifying the signal, the means for amplifying having an input coupled to an output of the means for impedance matching.

Clause 27: The apparatus of Clause 26, wherein the means for limiting comprises means for clamping the voltage of the signal.

Clause 28: The apparatus of Clause 26, wherein the means for limiting comprises means for clamping a voltage swing of the signal.

Clause 29: The apparatus of any of Clauses 26-28, further comprising means for amplifying another signal to generate the signal, wherein the means for amplifying the other signal has an output coupled to an input of the means for impedance matching.

Clause 30: The apparatus of any of Clauses 26-29, wherein the means for impedance matching comprises a shunt passive component and wherein the means for limiting is coupled to a tap of the shunt passive component.

Additional Considerations

The various operations or methods described above may be performed by any suitable means capable of performing the corresponding functions. The means may include various hardware and/or software component(s) and/or module(s), including, but not limited to a circuit, an application specific integrated circuit (ASIC), or processor. Generally, where there are operations illustrated in figures, those operations may have corresponding counterpart means-plus-function components with similar numbering.

For example, means for impedance matching may include a matching circuit, such as the inter-stage matching (ISM) circuit 404 depicted in and described above with respect to FIGS. 4A and 4B. Means for limiting a voltage of a signal may include an overvoltage protection (OVP) circuit, such as the overvoltage protection circuit 406 portrayed in and described above with respect to FIGS. 4A and 4B. Means for amplifying a signal may include an amplifier, such as the power amplifier (PA) 316 or the driver amplifier (DA) 314 shown in and described above with respect to FIGS. 3, 4A, and 4B.

As used herein, the term “determining” encompasses a wide variety of actions. For example, “determining” may include calculating, computing, processing, deriving, investigating, looking up (e.g., looking up in a table, a database, or another data structure), ascertaining, and the like. Also, “determining” may include receiving (e.g., receiving information), accessing (e.g., accessing data in a memory), and the like. Also, “determining” may include resolving, selecting, choosing, establishing, and the like.

As used herein, a phrase referring to “at least one of” a list of items refers to any combination of those items, including single members. As an example, “at least one of: a, b, or c” is intended to cover: a, b, c, a-b, a-c, b-c, and a-b-c, as well as any combination with multiples of the same element (e.g., a-a, a-a-a, a-a-b, a-a-c, a-b-b, a-c-c, b-b, b-b-b, b-b-c, c-c, and c-c-c or any other ordering of a, b, and c).

The methods disclosed herein comprise one or more steps or actions for achieving the described method. The method steps and/or actions may be interchanged with one another without departing from the scope of the claims. In other words, unless a specific order of steps or actions is specified, the order and/or use of specific steps and/or actions may be modified without departing from the scope of the claims.

The following claims are not intended to be limited to the aspects shown herein, but are to be accorded the full scope consistent with the language of the claims. Within a claim, reference to an element in the singular is not intended to mean “one and only one” unless specifically so stated, but rather “one or more.” Unless specifically stated otherwise, the term “some” refers to one or more. No claim element is to be construed under the provisions of 35 U.S.C. § 112(f) unless the element is expressly recited using the phrase “means for” or, in the case of a method claim, the element is recited using the phrase “step for.” All structural and functional equivalents to the elements of the various aspects described throughout this disclosure that are known or later come to be known to those of ordinary skill in the art are expressly incorporated herein by reference and are intended to be encompassed by the claims. Moreover, nothing disclosed herein is intended to be dedicated to the public regardless of whether such disclosure is explicitly recited in the claims.

What is claimed is:

1. A radio frequency front-end circuit comprising:
a power amplifier;
a matching circuit having an output coupled to an input of the power amplifier; and
an overvoltage protection circuit coupled to the matching circuit.

2. The radio frequency front-end circuit of claim 1, wherein the overvoltage protection circuit comprises a single branch of one or more diodes.

3. The radio frequency front-end circuit of claim 1, wherein the overvoltage protection circuit comprises a single branch with a plurality of series-connected diodes.

4. The radio frequency front-end circuit of claim 1, wherein the overvoltage protection circuit comprises:
a first branch of one or more first diodes arranged in a first direction; and
a second branch of one or more second diodes arranged in a second direction.

5. The radio frequency front-end circuit of claim 4, wherein the second direction is opposite to the first direction, such that the one or more first diodes in the first branch are anti-parallel with the one or more second diodes in the second branch.

6. The radio frequency front-end circuit of claim 4, wherein a first number of the one or more first diodes in the first branch is different from a second number of the one or more second diodes in the second branch.

7. The radio frequency front-end circuit of claim 4, wherein the first branch comprises a first diode coupled in series with a second diode and wherein the first diode is a different diode type than the second diode.

8. The radio frequency front-end circuit of claim 4, wherein a first diode type of at least one of the first diodes in the first branch is different from a second diode type of at least one of the second diodes in the second branch.

9. The radio frequency front-end circuit of claim 1, wherein the matching circuit comprises a shunt passive component and wherein the overvoltage protection circuit is coupled to a tap of the shunt passive component.

10. The radio frequency front-end circuit of claim 9, wherein the shunt passive component comprises an inductor.

11. The radio frequency front-end circuit of claim 1, wherein the matching circuit comprises a shunt branch having a first passive component connected in series to a second passive component and wherein the overvoltage protection circuit is coupled to a node between the first passive component and the second passive component.

12. The radio frequency front-end circuit of claim 11, wherein at least one of the first passive component or the second passive component comprises an inductor.

13. The radio frequency front-end circuit of claim 11, wherein the second passive component comprises a capacitor.

14. The radio frequency front-end circuit of claim 1, further comprising a driver amplifier, wherein an output of the driver amplifier is coupled to an input of the matching circuit.

15. A method of signal processing, comprising:
receiving a signal at a matching circuit;
limiting a voltage of the signal with an overvoltage protection circuit coupled to the matching circuit; and
amplifying the signal with a power amplifier.

16. The method of claim 15, wherein the limiting comprises clamping the voltage of the signal with a single branch of one or more diodes in the overvoltage protection circuit.

17. The method of claim 15, wherein the limiting comprises clamping the voltage of the signal with a plurality of series-connected diodes in the overvoltage protection circuit.

18. The method of claim 15, wherein the limiting comprises clamping a voltage swing of the signal with:
a first branch of the overvoltage protection circuit, the first branch having one or more first diodes arranged in a first direction; and
a second branch of the overvoltage protection circuit, the second branch having one or more second diodes arranged in a second direction.

19. The method of claim 18, wherein the second direction is opposite to the first direction, such that the one or more first diodes in the first branch are anti-parallel with the one or more second diodes in the second branch.

20. The method of claim 18, wherein a first number of the one or more first diodes in the first branch is different from a second number of the one or more second diodes in the second branch.

21. The method of claim 18, wherein the first branch comprises a first diode coupled in series with a second diode and wherein the first diode is a different diode type than the second diode.

22. The method of claim 18, wherein a first diode type of at least one of the first diodes in the first branch is different from a second diode type of at least one of the second diodes in the second branch.

23. The method of claim 15, further comprising amplifying another signal with a driver amplifier to generate the signal for the receiving at the matching circuit.

24. The method of claim 15, wherein the matching circuit comprises a shunt passive component and wherein the overvoltage protection circuit is coupled to a tap of the shunt passive component.

25. The method of claim 15, wherein the matching circuit comprises a shunt branch having a first passive component connected in series to a second passive component and wherein the overvoltage protection circuit is coupled to a node between the first passive component and the second passive component.

26. An apparatus for signal processing, comprising:
means for impedance matching;
means for limiting a voltage of a signal, the means for limiting being coupled to the means for impedance matching; and
means for amplifying the signal, the means for amplifying having an input coupled to an output of the means for impedance matching.

27. The apparatus of claim 26, wherein the means for limiting comprises means for clamping the voltage of the signal.

28. The apparatus of claim 26, wherein the means for limiting comprises means for clamping a voltage swing of the signal.

29. The apparatus of claim 26, further comprising means for amplifying another signal to generate the signal, wherein the means for amplifying the other signal has an output coupled to an input of the means for impedance matching.

30. The apparatus of claim 26, wherein the means for impedance matching comprises a shunt passive component and wherein the means for limiting is coupled to a tap of the shunt passive component.
